(19) United States
(12) Patent Application Publication
(10) Pub. No.: US 2009/0224287 A1
(43) Pub. Date: Sep. 10, 2009

(54) SEMICONDUCTOR DEVICE HAVING A LOCALLY BURIED INSULATION LAYER

(76) Inventors: Dong-Suk Shin, Yongin-si (KR); Ho Lee, Cheonan-si (KR); Myung-Sun Kim, Hwaseong-si (KR)

Correspondence Address: F. CHAU & ASSOCIATES, LLC, 130 WOODBURY ROAD, WOODBURY, NY, 11797, US

(21) Appl. No.: 12/400,408

(22) Filed: Mar. 9, 2009

(30) Foreign Application Priority Data
Mar. 10, 2008 (KR) 10-2008-0021964

(51) Int. Cl. H01L 29/80

(52) U.S. Cl. 257/192; 257/E29.31

(57) ABSTRACT

A semiconductor device having a locally buried insulation layer and a method of manufacturing a semiconductor device having the same are provided, in which a gate electrode is formed on a substrate, and oxygen ions are implanted into an active region to form a locally buried insulation layer. An impurity layer is formed on the locally buried insulation layer to form a source/drain. A silicide layer is formed on the source/drain and on the gate electrode. The locally buried insulation layer can prevent junction leakage, decrease junction capacitance and prevent a critical voltage of an MOS transistor from increasing due to body bias, thereby to improve characteristics of the device.

This application claims priority under 35 USC §119 to Korean Patent Application No. 2008-21964, filed Mar. 10, 2008 in the Korean Intellectual Property Office, the contents of which are herein incorporated by reference in their entirety.

### BACKGROUND

1. Technical Field

Exemplary embodiments of the present invention relate to a semiconductor device and a method of manufacturing the semiconductor device. More particularly, exemplary embodiments of the present invention relate to a semiconductor device having a transistor structure including a source/drain of a heterojunction structure capable of inducing a stress layer effect and a locally buried insulation layer to improve electrical properties of the device, and a method of manufacturing the same.

2. Discussion of Related Art

Generally, in semiconductor devices, an individual element, such as a metal oxide semiconductor LOS) transistor, is employed as a switching device. As the degree of integration of semiconductor devices has been increasing, MOS transistors are being scaled down in size. As a result, the channel length of a MOS transistor may be decreased so much as to cause a short channel effect. Also, due to the reduction of space in a channel region, insulation between the elements is limited and junction leakage increases. The decrease of the channel length also results in a lowering of the width of a gate electrode. Accordingly, the electrical resistance of the gate electrode is increased, and thus a critical voltage of the MOS transistor increases due to body bias, thereby decreasing a switching speed. In order to overcome problems in conventional MOS transistors, it may be required to provide a semiconductor device capable of reducing resistances of a source/drain region and a gate and preventing the junction leakage, which also providing high-speed operation.

In order to overcome these disadvantages in conventional semiconductor devices, U.S. Pat. No. 5,930,642 discloses a method of manufacturing a semiconductor device using a silicon-on-insulator (SOD) substrate to provide an MOS transistor.

The method of manufacturing a semiconductor device using the SOI substrate may have some disadvantages in that the manufacturing cost of the SOI substrate is relatively high, and the resistance of the source/drain is increased, thereby deteriorating characteristics of the device. In order to overcome these disadvantages, a silicidation process is widely used. In the silicidation process, a metal silicide layer is selectively formed on the gate electrode and the source/drain region to reduce the electrical resistances of the gate electrode and the source/drain region. Various silicidation processes using a metal, such as cobalt, nickel, and the like, have been developed. Because the metal, such as cobalt or nickel, needs to be formed in a shallow junction layer, however, it may be considerably difficult to perform the process. In particular, junction destruction due to a silicide spike or leakage due to the shallow junction may have some adverse effect on the device.

The transmission speed of the electrical signal may depend on the resistance of the source/drain and the electrode. Also, the transmission speed may be closely related with the mobility of electrical charges. Recent research has reported that stress can be applied to the channel region to thereby increase the transmission speed. U.S. Patent Laid-Open Publication No. 2007/0134859 discloses a method of applying stress to the channel region and a structure for applying the stress to the channel region to make the transistor switch faster.

FIG. 1 is an electron microscope image illustrating a cross-section of a conventional semiconductor device.

As illustrated in FIG. 1, generally a gate sidewall layer may be formed to surround sidewalls of a gate electrode, to thereby diffuse stress and not concentrate the stress on a channel. Therefore, as illustrated in the image, in a logic device requiring a high operational speed, the gate sidewall layer may be removed to strain the channel. When the gate sidewall layer is slightly over-etched though a dry etch process, a source/drain region is excessively etched, and thus a recessed structure, recessed under both sides of the lower sidewalls of the gate electrode, as illustrated in the image of FIG. 1, is formed in an active region by the stress, so as to cause junction leakage. Because the device is highly integrated, the structure may deteriorate the performance of the device that requires the shallow junction of the source/drain region. In particular, in a semiconductor device having a structure where a material layer, such as a spacer, on the sidewalls of the gate electrode are properly removed to sufficiently obtain a stress layer effect, excessive etching may need to be performed to sufficiently remove the gate sidewall layer. In this case, the attack may be so large as to cause junction leakage, thereby deteriorating the performance of the device.

### SUMMARY OF THE INVENTION

Exemplary embodiments of the present invention provide a semiconductor device including a transistor structure having a source/drain of a heterojunction structure formed in a substrate on a side of a lower sidewall of a gate electrode to induce a stress layer effect, thereby improving electrical properties and reliability.

Exemplary embodiments of the present invention provide a method of manufacturing a semiconductor device including forming a locally buried insulation layer under the source/drain region to prevent junction leakage.

According to exemplary embodiments, in a method of manufacturing a semiconductor device, a gate electrode is formed on a substrate. After a first sidewall pattern is formed on sidewalls of the gate electrode, the first sidewall pattern is used as a mask to form a recess in an active region. Oxygen ions are implanted into the substrate that is exposed through the recess to form a locally buried insulation layer. Silicon in the substrate is used as a seed to fill the recess using an epitaxial growth process. In an exemplary embodiment a material having a heterojunction structure is filled in the recess to increase a stress layer effect. In order to sufficiently induce the stress layer effect after forming the first gate sidewall pattern and following forming second and third gate sidewall patterns, a sidewall structure is provided to serve as an etch-stop layer to prevent attacks that are caused on an active region when the sidewall patterns are removed or are formed to be very small.

In exemplary embodiments, the locally buried insulation layer may be formed in the active region layer that is provided as a protective layer for preventing junction leakage and thereby to prevent electrical problems.

In exemplary embodiments, a source/drain region may include the locally buried insulation layer, and the source/drain may have a heterojunction structure. A metal silicide layer may be formed on an impurity region provided as the source/drain and on the gate electrode, to provide a device having low electrode resistance and low junction resistance. Furthermore, a gate electrode structure having the sufficiently removed sidewall pattern formed on the sidewall of the gate electrode may be provided to increase the stress layer effect.

In exemplary embodiments, a gate dielectric layer may be formed on the semiconductor substrate and the gate electrode pattern may be formed on the gate dielectric layer. The first sidewall pattern may be formed on the gate electrode, and then the first sidewall pattern may be used as a mask to form the recess. In an exemplary embodiment, the semiconductor device may be a complementary semiconductor device having an n-type field effect transistor (n-FET) metal-oxide semiconductor (MOS) transistor and a p-type field effect transistor (p-FET) MOS transistor. For example, the recess may be formed in both the n-FET region and the p-FET region. Alternatively, the recess may be formed only in the p-FET region. The oxygen ions may be implanted under surfaces of the recess, and the implanted oxygen ions may be thermally treated to form the locally buried insulation layer. Then, the recess may be filled by an epitaxial growth process using the substrate exposed through the recess as a seed. An epitaxial buried layer filling the recess may include a material having a different lattice structure from the channel region to concentrate stress on the channel, to thereby increase the operation speed of the device. The recess in the p-FET may be filled with a silicon germanium layer including boron to concentrate stress on the channel.

In exemplary embodiments, the gate sidewall pattern may be formed on a lower sidewall of the gate electrode, not on an upper portion or on an upper sidewall of the gate electrode, thereby to concentrate the stress on the channel. Thus, the mobility of electrical charges may be increased in order to increase the operating speed of the device.

According to exemplary embodiments, in a method of manufacturing a semiconductor device, a gate electrode is formed on a substrate. A recess is formed in a substrate using a gate sidewall. A locally buried insulation layer is formed under the recess to be provided as a leakage protective layer. The recess is filled to form a source/drain having a heterojunction structure and a metal silicide layer is formed, thereby forming a device capable of preventing attacks that are caused on the active region by the gate sidewall pattern and concentrating stress in the sidewall and the heterojunction structure of the source/drain region to the channel.

According to exemplary embodiments, a semiconductor device includes a locally buried insulation layer with no junction leakage and a metal silicide layer to improve electrical properties of the device.

Furthermore, a semiconductor device includes a source/drain of a heterojunction structure and a gate electrode structure capable of concentrating stress on a channel, in order to improve the electrical properties thereof.

### BRIEF DESCRIPTION OF THE DRAWINGS

Exemplary embodiments of the present invention will be more clearly understood from the following detailed descriptions taken in conjunction with the accompanying drawings.

FIG. 1 is an electron microscope image illustrating a cross-section of a conventional semiconductor device.

FIGS. 2 to 14 are cross-sectional views illustrating a method of manufacturing a semiconductor device in accordance with an exemplary embodiment of the present invention.

FIGS. 15 to 29 are cross-sectional views illustrating a method of manufacturing a semiconductor device in accordance with an exemplary embodiment of the present invention.

FIGS. 30 to 44 are cross-sectional views illustrating a method of forming a semiconductor device in accordance with an exemplary embodiment of the present invention.

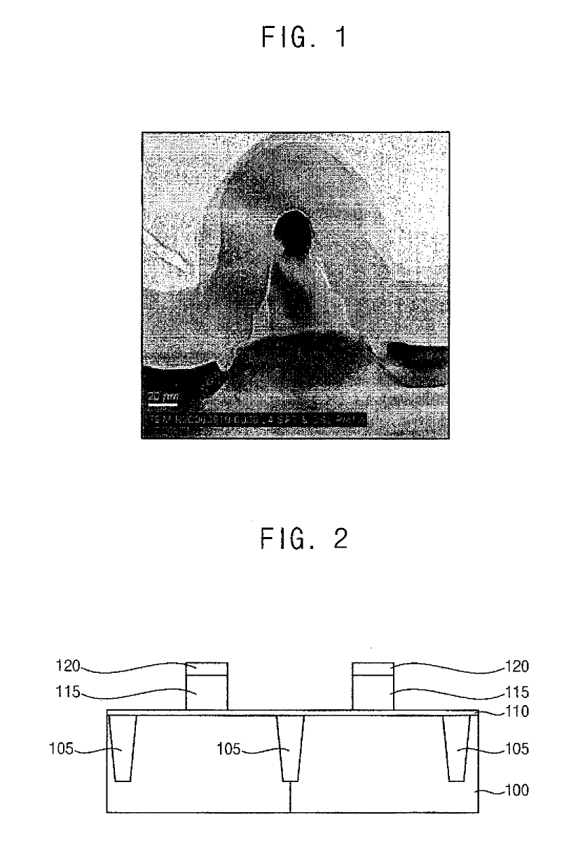

### DETAILED DESCRIPTION OF EXEMPLARY EMBODIMENTS

This application claims priority under 35 U.S.C. §119 to Korean Patent Application No. 2008-21964, filed on Mar. 10, 2008 in the Korean Intellectual Property Office (KIPO), the contents of which are herein incorporated by reference in their entirety.

Various exemplary embodiments of the present invention will be described more fully hereinafter with reference to the accompanying drawings, in which some exemplary embodiments are shown. The present invention may, however, be embodied in many different forms and should not be construed as limited to the exemplary embodiments set forth herein. Rather, these exemplary embodiments are provided so that this disclosure will be thorough and complete, and will fully convey the scope of the present invention to those of ordinary skill in the art. In the drawings, the sizes and relative sizes of layers and regions may be exaggerated for clarity.

Exemplary embodiments of the present invention are described herein with reference to cross-sectional illustrations that are schematic illustrations of idealized exemplary embodiments and intermediate structures. As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms, including technical and scientific terms, used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

FIGS. 2 to 14 are cross-sectional views illustrating a method of manufacturing a semiconductor device in accordance with an exemplary embodiment of the present invention.

Referring to FIG. 2, in a semiconductor device according to the present exemplary embodiment, a plurality of isolation layers 105 is formed in a substrate 100. The isolation layers 105 are spaced apart from one another by a predetermined distance. The substrate 100 may comprise a semiconductor substrate, such as a silicon wafer. The substrate 100 may include an n-type field effect transistor (n-FET) metal-oxide semiconductor (MOS) transistor region (not shown in FIG. 2) and a p-type field effect transistor (p-FET) MOS transistor region (not shown in FIG. 2). In the n-FET MOS transistor region, a p-type well is formed in the substrate and an n-type source/drain is formed in the substrate on both sides of a gate electrode. In the p-FET MOS transistor region, an n-type well is formed in the substrate and a p-type source/drain is formed in the substrate on both sides of a gate electrode. Accordingly, before and after forming the isolation layer, each of the wells corresponding to the n-FET region and the p-FET region may be formed in the substrate in order to form a complementary semiconductor transistor. As illustrated in the figures, each of the n-FET region and the p-FET region may be exposed relatively differently by a photolithography process, and then corresponding conductive type impurities may be respectively implanted into the n-FET region and the p-FET region by a selective ion implantation process, to form the corresponding well.

The isolation layer 105 may be formed by a shallow trench isolation process. The isolation layer 105 may be formed using a material having excellent gap-fill characteristics. Examples of such a material are a high-density plasma chemical vapor deposition (HDP-CVD) oxide, high-temperature undoped silicate glass (HT-USG), ozone-tetraethyl orthosilicate (O3-TEOS), spin-on glass (SOG), and the like. The isolation layer 105 may have a single layer structure or a multilayer structure used in combination therewith.

Referring again to FIG. 2, a gate dielectric layer 110 is formed on the substrate 100. The gate dielectric layer 110 may be formed of an oxide using a thermal oxidation process. Alternatively, the gate dielectric layer 110 may have a multilayer structure including an oxide layer and an oxide layer having nitride. Alternatively, the gate dielectric layer 110 may be formed using metal oxide as a ferroelectric material according to the gate electrode material. The gate dielectric layer 110 may have a thickness of about 30 Å to about 100 Å. A plasma nitridation process may be further performed on the gate dielectric layer 110 to improve surface characteristics of the gate dielectric layer 110.

A gate electrode 115 may be a polysilicon layer or a metal electrode layer. In this exemplary embodiment, the gate electrode 115 may be the polysilicon layer to subsequently receive a metal silicide layer to be formed thereon. The polysilicon layer may be formed by a chemical vapor deposition (CVD) process and then impurities may be implanted into the polysilicon layer to provide the desired properties. The impurities may be implanted together with the chemical deposition. Alternatively, the impurities may be implanted by an ion implantation process. The gate electrode 115 may have a thickness of about 1,000 Å to about 3,000 Å. A gate hard mask 120 is formed on the gate electrode 115. The gate hard mask 120 may be formed using an oxide layer or a nitride layer. The gate hard mask 120 may have a sufficient thickness to protect the gate electrode during subsequent processes. The gate hard mask may have a thickness of about 1,000 Å to about 3,000 Å. As illustrated in the figures, a photoresist pattern for the gate electrode may be formed on the gate hard mask layer (not illustrated) and then the gate hard mask layer may be etched to form the gate hard mask 120. The gate hard mask 120 may be used as an etching mask to form the gate electrode 115.

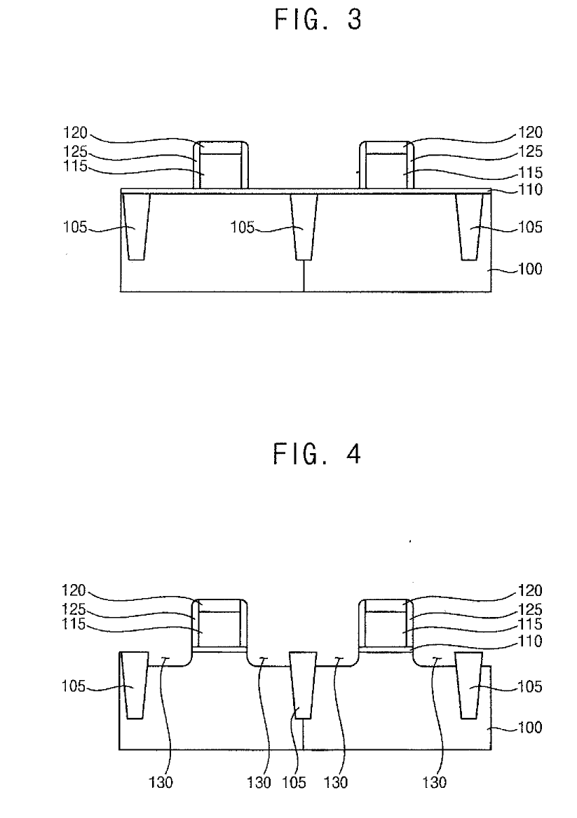

Referring to FIG. 3, a first gate sidewall layer 125 is formed on sidewalls of the gate electrode 115. Instead of a process for forming the gate sidewall layer 125, a gate reoxidation process may be performed. The gate reoxidation process may compensate for damage due to a dry etch process used for forming the gate electrode and can develop an edge portion of the gate dielectric layer into a bird's beak shape to reduce parasitic capacitance between the gate and the drain, to thereby improve characteristics of the device. Accordingly, a thermal oxidation process may be performed to form the first gate sidewall layer 125 and a general gate reoxidation process may be performed together. The first gate sidewall layer 125 may have a thickness of less than about 200 Å.

Referring to FIG. 4, the substrate 100 is partially etched using the first gate sidewall layer 125 and the gate hard mask 120 as an etching mask by an anisotropic etch process to form recesses 130 in the substrate 100. For example, in order to form the recesses 130, first, a dry etch process may be performed and then a wet etch process may be performed to compensate for damage due to the dry etch process and planarize the surfaces of the recesses 130. Because a source/drain region is formed in the recesses 130 by a subsequent process, the depth of the recesses 130 may be controlled according to the characteristics of the device. The depth of the recesses 130 may range from about 30 nm to about 150 nm. The depth of the recesses 130 may be the same as or greater than that of the source/drain region.

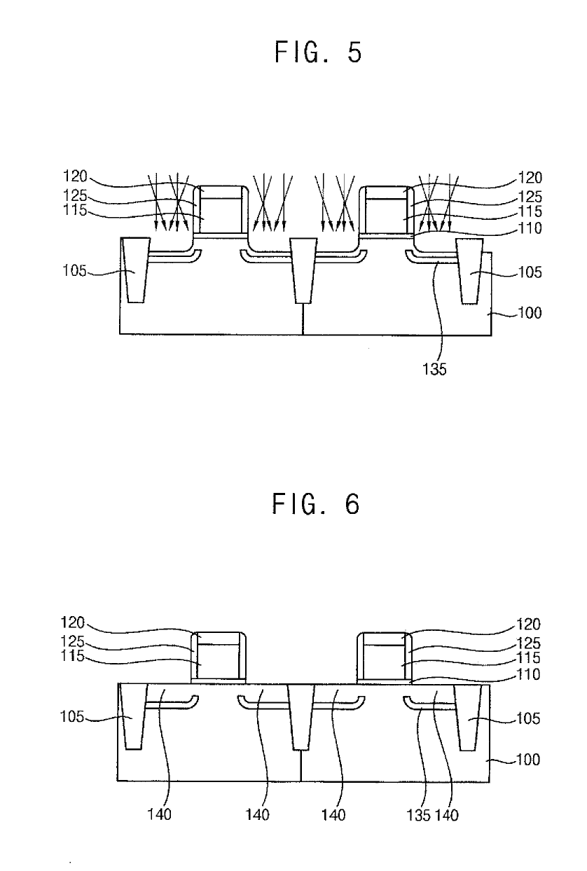

Referring to FIG. 5, oxygen ions are implanted into the surface of the substrate 100 exposed through the recesses 130 to form a locally buried insulation layer 135. The oxygen ions may be implanted under the surface of the recess 130 by an ion implantation process represented by arrows in FIG. 5. Because the buried depth of the insulation layer may depend on the implantation energy, the implantation energy will be determined according to the specific kind of device. According to the shape of the source/drain to be formed, the oxygen ions are implanted into the substrate at a predetermined angle and, thus, the locally buried insulation layer 135 may have a linear profile under the source/drain region and an arc profile under the gate electrode. Also, the oxygen ions may be symmetrically implanted into the substrate on both sides of the gate electrode, such that the source/drain regions on both sides of the gate electrodes are formed to be symmetric to each other. The locally buried insulation layer 135 can prevent the downward leakage in the source/drain region and can suppress lateral depletion in the source/drain region under the channel region during operation of the device, thereby to prevent the short channel effect. Accordingly, the locally buried insulation layer 135 may be bent upwardly at the ends thereof to have an arc shape under the gate electrodes. When an upper end portion of the arc shape reaches a low concentration source/drain region, the locally buried insulation layer 135 can completely prevent the short channel effect.

Referring to FIG. 6, epitaxial buried layers 140 are formed using silicon in the semiconductor substrate 100 as a seed by an epitaxial growth process to fill the recesses 130 shown in FIG. 4. For example, single-crystalline silicon or single-crystalline silicon germanium may be grown in the recesses 130 to form the epitaxial buried layers 140. When the epitaxial buried layers 140 are formed of a silicon germanium layer, a lattice-mismatched region may be formed in the adjacent silicon substrate by the silicon germanium layer, that can be used to induce strain on the channel region. For example, the lattice-mismatched region may be formed by an epitaxial process such as an ultra high vacuum CVD process and a molecular beam epitaxy (MBE) process. The silicon germanium stressor may be doped in-situ with boron. For example, the silicon germanium buried layer 140 formed in the source/drain region of the p-FET may apply stress to the channel region of the p-FET, to thereby improve characteristics of the device. The single-crystalline silicon may be more easily grown to form the epitaxial buried layers 140 than the single-crystalline silicon germanium, but the epitaxial buried layers 140 including the silicon layer may not sufficiently concentrate the stress on the channel region. Therefore, the single-crystalline silicon germanium may be grown in a region for the source/drain region of at least the p-FET to be formed there, to thereby increase the operating speed of the device.

In the above-described exemplary embodiment, the single-crystalline silicon germanium may be grown in regions in which the source/drain regions of both the p-FET and the n-FET are to be formed. In this case, the process may be simple; however, the silicon germanium buried layers 140 may apply stress to the channel region of the p-FET thereby to improve the operating speed of the device, whereas the silicon germanium buried layers 140 may not apply any stress to the channel region of the n-FET due to a different channel carrier and different stress dynamics at the n-FET. In order to compensate for stress related problems, for example, a sidewall length of the gate electrode may be controlled to form a gate structure capable of concentrating the stress on the channel region.

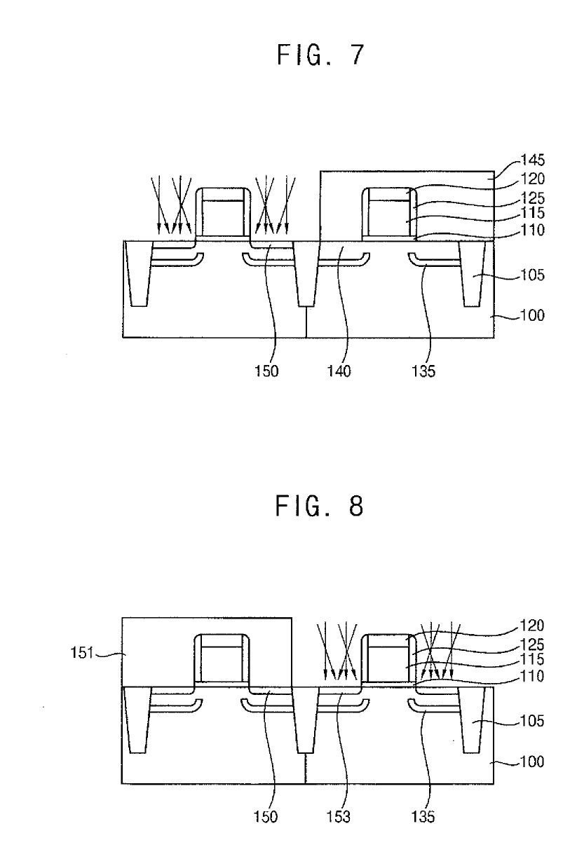

Referring to FIG. 7, an n-type low concentration impurity region 150 is formed in an active region of the n-FET to be subsequently formed. After a photoresist pattern 145 is formed to cover a region of the p-FET to be subsequently formed, n-type impurities may be implanted into the substrate by an ion implantation process to form the low concentration impurity region 150. Because the low concentration impurity region is provided as a low concentration source/drain, and if the junction is formed deeply, the impurity region is formed laterally to consume the gate channel length, thereby deteriorating characteristics of the device. Thus, the implantation energy may be controlled to form the impurity region having a relatively small depth. Also, in order to reduce a shadow effect due to the height of the gate, the impurities may be implanted by a symmetry ion implantation process, or they may be implanted into the substrate at an implantation angle of 90° with respect to the substrate.

Referring to FIG. 8, a p-type low concentration impurity region 153 is formed in an active region of the p-FET to be subsequently formed. After a photoresist pattern 151 is subsequently formed to cover a region of the n-FET to be formed, p-type impurities may be implanted into the substrate by an ion implantation process. This process may be substantially the same as the process explained with reference to FIG. 7, except for a conductive type of the ion implantation impurities. Alternatively, the process of FIG. 7 may be performed to follow the process of FIG. 8.

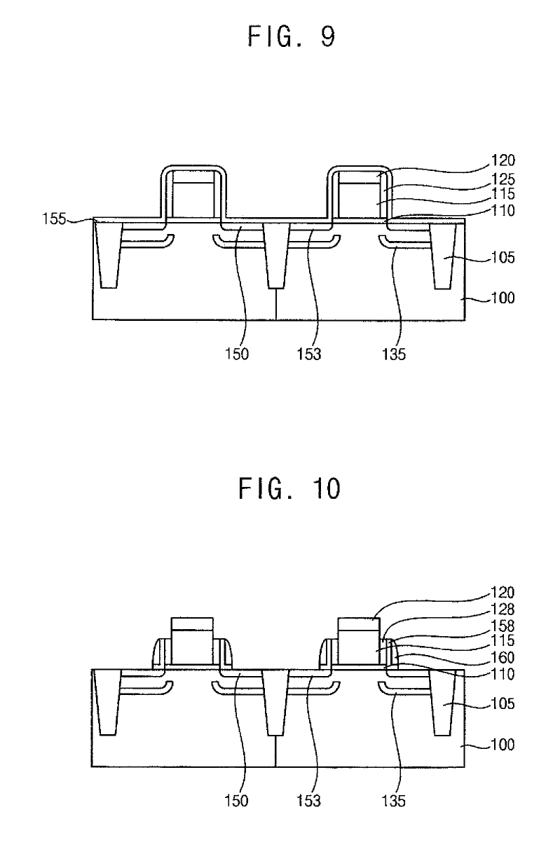

Referring to FIG. 9, after forming the low concentration impurity regions 150 and 153 in the substrate in which the n-FET and the p-FET are subsequently formed, the photoresist pattern is removed and a cleaning process is performed on the semiconductor substrate. A second gate sidewall layer 155 is then formed on the substrate. The second gate sidewall layer 155 may be formed using a nitride layer having different properties from the first gate sidewall layer 125. The second gate sidewall layer 155 may have a thickness of about 100 Å to about 500 Å, and the second gate sidewall layer 155 may be formed by a CVD process. The second gate sidewall layer 155 may include a material having an etch rate smaller than that of a third gate sidewall layer, thereby to protect the substrate from attack caused during a subsequent forming of a third gate sidewall pattern (see FIG. 10).

Referring to FIG. 10, after the third gate sidewall layer (not illustrated) is formed on the second gate sidewall layer 155, the first, second and third gate sidewall layers are patterned to form a first gate sidewall pattern 128, a second gate sidewall pattern 158 and a third gate sidewall pattern 160. The gate sidewall patterns may be formed by an etch-back process. The second sidewall layer 155 may have a sufficient thickness and an etch rate different from the third sidewall layer, to protect the substrate from the attack caused during subsequent forming of the third gate sidewall pattern 160. Also, the second gate sidewall pattern 158 may have a sufficient thickness and structure, so that the second gate sidewall pattern on a lower portion of the gate electrode concentrates the stress on the channel region. For example, the second gate sidewall pattern 158 may be formed to have an L-shape structure and may be positioned under the lower portion of the gate electrode. In this exemplary embodiment, the silicon germanium layer is formed of the substrate in the p-FET to concentrate stress on the channel region thereof. Although the silicon germanium layer is formed in the substrate of the n-FET, the desired stress concentration effect may not be obtained due to the different channel carrier and the different stress dynamics at the n-FET. Accordingly, it may be necessary not to provide the stress in the gate sidewall pattern. Therefore, the size of the gate sidewall structure may need to become smaller. If the third gate sidewall is excessively etched in order to form the small gate structure, an attack may cause damage to the substrate. In this exemplary embodiment, in order to prevent the attack, the gate sidewall may be removed using the second gate sidewall layer 155. A spacer may be formed initially and then the spacer may be etched, so that the gate sidewall patterns are not formed on the upper portion and the upper sidewall of the gate electrode 115. The gate sidewall patterns may be formed only on the middle portion and the lower portion of the gate electrode in order to concentrate the stress on the channel region.

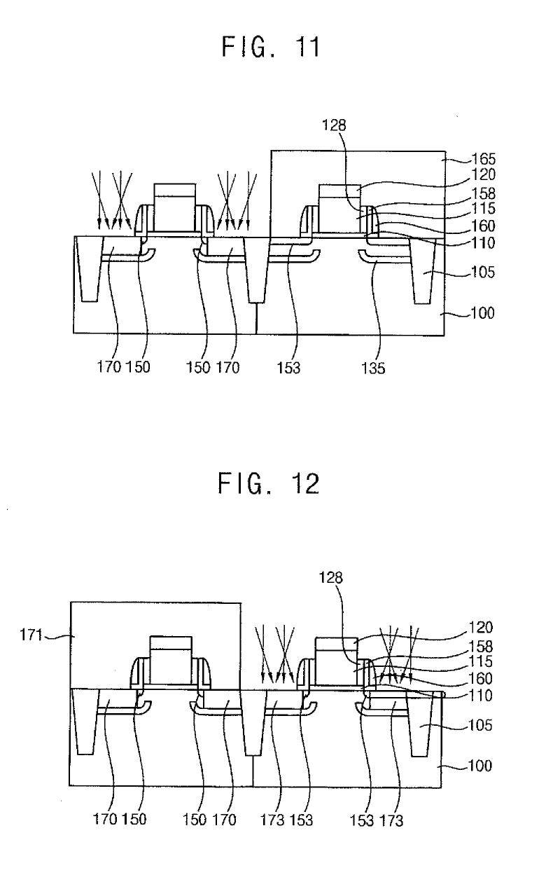

Referring to FIG. 11, the third gate sidewall pattern 160 is used as a mask for an n-type high concentration impurity region 170 in the region in which the n-FET MOS transistor will be subsequently formed. The n-type high concentration impurity region 170 may be positioned on the locally buried insulation layer 135. As illustrated in FIG. 11, the locally buried insulation layer may prevent diffusion of the high concentration source/drain region 170.

Referring to FIG. 12, impurities having a different conductive type are implanted to the substrate for subsequently forming the p-FET MOS transistor, in order to form a complementary semiconductor device. In this case, a mask 171 may cover the region for the subsequently formed n-FET.

Because the high concentration impurity regions 170 and 173 are provided as a high concentration source/drain, a metal silicide may be formed in the high concentration regions 170 and 173 by a subsequent process, the photoresist pattern and the gate hard mask 120 are removed by a wet etch process. In this exemplary embodiment, when the gate sidewall structures are formed toward a lower edge of the gate electrode, the stress concentration effect may be increased. Accordingly, after implanting the impurities, the sizes of the second and third gate sidewall patterns 158 and 160, respectively, may be further reduced to enhance the stress concentration effect.

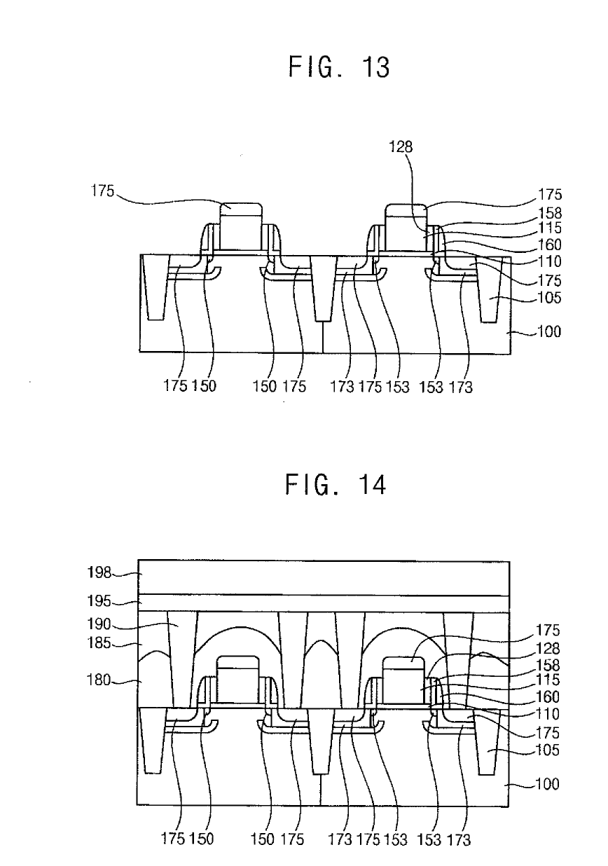

Referring to FIG. 13, a metal silicide layer 175 is formed on the gate electrode 115 and on the high concentration impurity regions 170 and 173. The metal silicide layer 175 may be formed using a metal, such as cobalt, nickel and titanium, and the metal silicide layer 175 may be formed by a sputtering process. Because the thickness of the silicide layer 175 is closely related with the resistance of the source/drain region, it may be preferable for the silicide layer 175 to have a relatively large thickness. When the silicide layer 175 is formed to have a specific large thickness, however, the silicide layer 175 may result in a structure in which the source/drain region is broken down by a spike effect. Accordingly, first a low-temperature silicide layer may be formed to have a thickness of less than 200 Å by a low temperature process at a temperature of 150° C. to 450° C. For example, when cobalt is used as the silicide layer, the low-temperature silicide layer may be Co₂Si or CoSi. Accordingly, a second high-temperature process may need to be performed in order to complete the silicidation reaction. Additionally if necessary, a capping layer such as a titanium/titanium nitride layer may be formed on the metal silicide layer 175. For example, the capping layer may be formed by a CVD process at a temperature of 300° C. to 700° C. In this case, the second high-temperature process may be omitted. The high-temperature annealing process may need to be performed to change the cobalt suicide structure, such as Co₂Si or CoSi, into a high-temperature-layered silicide structure having improved conductivity, such as CoSi₂.

Because it is more advantageous that the metal silicide layer 175 formed on the high concentration impurity regions 170 and 173 has a relatively small thickness in order to prevent the spike effect that causes the structure of the source/drain region to break down, the metal silicide layer 175 formed on the gate electrode 115 has a relatively large thickness in order to reduce the gate electrode resistance, because there is no problem about destruction of the junction. Alternatively, although not illustrated in the figures, the metal silicide layers 175 formed on the impurity regions and the gate electrode may be formed to have different respective thicknesses.

Then, the unreacted metal layer is removed by a wet etch process. Surfaces of the remaining metal silicide layer are oxidized by a plasma oxidation process or a thermal treatment process. The oxide layer may be used as an etch-stop layer during a subsequent contact forming process. Furthermore, if there are any problems related to a contact resistance, after the contact forming process, the oxide layer may be removed by a wet etch process. Alternatively, instead of the oxidation process, a nitridation process may be performed to achieve the same effect.

Referring to FIG. 14, after a first insulation interlayer 180 and a second insulation interlayer 185 are formed on the structure and a contact hole is formed by a photolithography process, a metal contact plug 190 to be connected to a metal wiring is formed in the contact hole. For example, the first and second insulation interlayers 180 and 185 may include a material, such as high-density plasma (HDP), borophosphosilicate glass (BPSG) and plasma-enhanced tetraethyl orthosilicate (PE-TEOS). These materials may be selectively used according to the characteristics or the structure of the device. As degrees of the integration of these semiconductor devices have been increasing, there have been made various demands for the insulation interlayer. For example, the insulation interlayer having a required capacitance may be used in order to reduce parasitic capacitance between adjacent wirings and to meet the required operating speed of the device.

As described above, an ending point of the contact hole forming process may be determined by detecting the cobalt oxide or nitride formed on the metal silicide layer 175. In this exemplary embodiment, after forming the contact hole, the oxide or nitride may be removed by a wet etch process to reduce the contact resistance.

The metal contact plug 190 may include a material such as aluminum, tungsten and copper. The materials may be selectively used for the contact plug 190 according to the required characteristics of the device, and thus the processes of forming the contact hole and filling the metal material may be determined according to the selected material.

Finally, a plurality of metal wirings 195, an insulation layer for protecting and insulating the wirings and a protective layer 198 for protecting the entire device are formed by subsequent processes. Then, a connection pad (not illustrated) is formed for electrical connection to an external system (not shown), to complete the semiconductor device.

As mentioned above, in this exemplary embodiment, the locally buried insulation layers are formed in the active regions of the n-FET and p-FET MOS transistors, wherein the source/drain region is formed on the locally buried insulation layer so as to have a lattice structure that may be used to cause stress to the locally buried insulation layer, and the gate sidewall patterns are formed only on the lower portion of the gate electrode. A device formed according to this exemplary embodiment can prevent the junction leakage and can provide high-speed operation.

FIGS. 15 to 29 are cross-sectional views illustrating a semiconductor device in accordance with an exemplary embodiment of the present invention. Most processes of the present exemplary embodiment are substantially the same as those in the above-described exemplary embodiment. Thus, any corresponding processes will be explained compared with the above-described exemplary embodiment and any further repetitive explanation concerning the same process will be omitted and only particular features in the present exemplary embodiment will be mainly explained. Further, additional features that are not specifically noted in the above-described exemplary embodiment will be explained.

Referring to FIG. 15, in a semiconductor device according to the present exemplary embodiment shown therein, a plurality of isolation layers 205 is formed in a substrate 200. The isolation layers 205 are spaced apart from one another by a predetermined distance. The substrate 200 may be formed of a semiconductor substrate such as a silicon wafer. In the present exemplary embodiment, a gate dielectric layer 210, a gate electrode 215 and a gate hard mask 220 are substantially the same as in the above-described exemplary embodiment.

A gate sidewall sacrificial layer 223 is formed on the substrate 200 and the gate structure. The gate sidewall sacrificial layer 223 is used as a mask while a recess is formed in the p-FET MOS transistor region, and then it is removed. The gate sidewall sacrificial layer 223 may be formed by a CVD process or a thermal oxidation process. In the case of the thermal oxidation process, the gate sidewall sacrificial layer 223 may be formed by a gate reoxidation process. The gate reoxidation process can compensate for damage due to a dry etch process for forming the gate electrode and develop an edge portion of the gate dielectric layer into a bird's beak shape to reduce parasitic capacitance between the gate and the drain, to thereby improve characteristics of the device. Although the gate dielectric layer 210 adjacent to an end portion of the gate electrode 215 may be damaged by the process used for forming the gate electrode 215, the integrity of the gate dielectric layer 210 may be recovered by a thermal oxidation process. Also the thickness of the gate dielectric layer 210 may be increased to be more capable of enduring a strong field applied to the device. When hot carriers passing through the channel reach the end portion of the gate electrode, the hot carriers may be induced by the strong field to cause damage to the gate dielectric layer. The gate dielectric layer formed through the thermal oxidation process, however, may be capable of enduring the damage of the hot carriers, thereby to provide improved reliability. Alternatively, when the gate sidewall sacrificial layer is formed by a CVD process, the gate sidewall sacrificial layer may be used as a mask for forming the recess and then a thermal oxidation layer may be used to form a first gate sidewall layer to achieve the same effect.

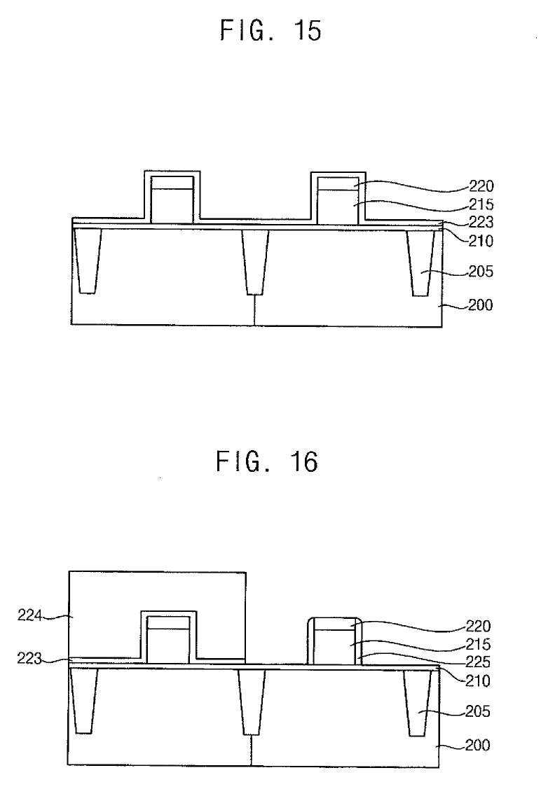

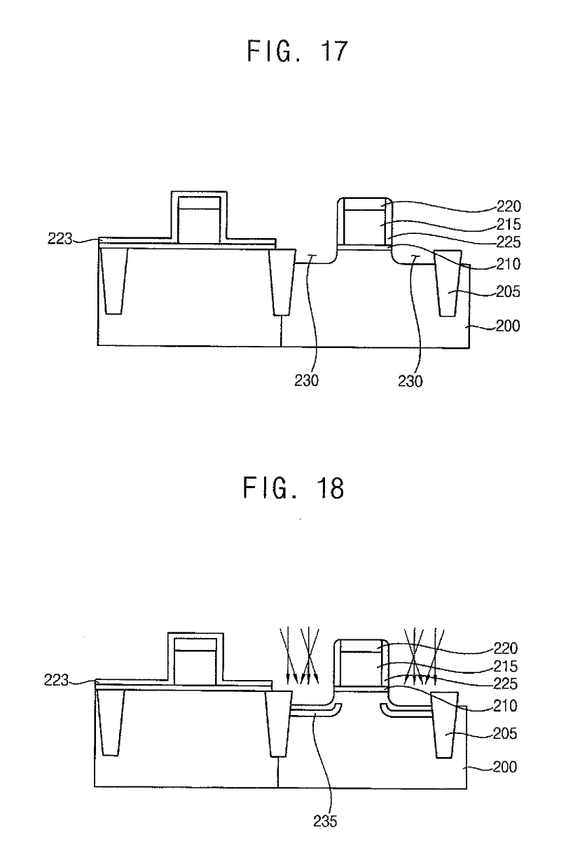

Referring to FIGS. 16 and 17, after a photoresist pattern 224 is formed to cover a region for the n-FET MOS transistor to be subsequently formed, an anisotropic process is performed on the substrate in a region for the p-FET MOS transistor to be subsequently formed, to form a gate sacrificial layer pattern 225 on the sidewalls of the gate electrode of the p-FET MOS transistor. The substrate is removed using the gate sacrificial layer pattern 225 as an etching mask to form recesses 230 in the p-FET MOS transistor region. For example, initially a dry etch process is performed on the substrate, and then a wet etch process is performed to compensate for damage to the substrate caused by the dry etch process and to planarize the surfaces of the recesses. Because a source/drain region is formed in the recesses 230 by a subsequent process, the depth of the recesses 230 may be controlled according to the characteristics of the device. For example, the depth of the recesses 230 may range from about 30 nm to about 150 nm. Also, the depth of the recess 130 may be the same as or greater than that of the source/drain region.

Referring to FIG. 18, oxygen ions are implanted into the surface of the substrate 200 exposed through the recesses 230 in the p-FET MOS transistor region to form a locally buried insulation layer 235. The oxygen ions may be implanted under the surface of the recesses 230 by an ion implantation process represented by the arrows in FIG. 18. Because the buried depth of the insulation layer may depend on the implantation energy, the implantation energy may be determined according to the device. According to the shape of the source/drain to be formed, the oxygen ions are implanted into the substrate at a predetermined angle, and thus the locally buried insulation layer 235 may have a linear profile under the source/drain region and an arc profile in which an end portion under the gate electrode is bent upwardly. Also, the oxygen ions may be symmetrically implanted into the substrate on both sides of the gate electrode such that the source/drain regions on both sides of the gate electrodes are formed to be symmetric to each other. After implanting the oxygen ions, a thermal treatment process may be performed such that the implanted oxygen ions are reacted with the substrate under an oxygen atmosphere to form the locally buried insulation layer 235. The locally buried insulation layer 235 can prevent the downward leakage in the source/drain region and suppress lateral depletion in the source/drain region under the channel region during operation of the device, thereby to prevent the short channel effect. Accordingly, the locally buried insulation layer 235 may be bent upwardly to have an arc shape. When the upper end portion of the arc shape reaches a low concentration source/drain region, the locally buried insulation layer 235 can completely prevent the short channel effect.

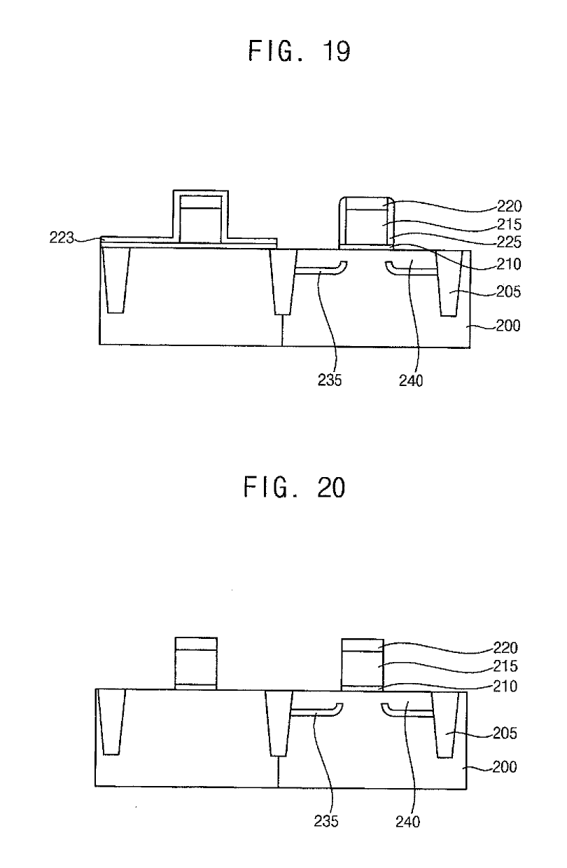

Referring to FIG. 19, an epitaxial buried layer 240 is formed using silicon in the semiconductor substrate 200 as a seed by an epitaxial growth process to fill the recesses 230 that was formed in the p-FET MOS transistor region. For example, single-crystalline silicon germanium that is different from the substrate material may be grown in the recesses 230 to form the epitaxial buried layers 240. When the epitaxial buried layers 240 include a silicon germanium layer, lattice-mismatched regions may be formed in the adjacent silicon substrate 200 by the silicon germanium layers, to apply stress to the channel regions. For example, the lattice-mismatched regions may be formed by an epitaxial process, such as an ultra high vacuum CVD process and a molecular beam epitaxy (MBE) process. The silicon germanium stressor may be doped in-situ with boron. For example, the silicon germanium buried layers 240 formed in the source/drain region of the p-FET can apply stress to the channel region of the p-FET, to thereby improve operating speed characteristics of the device. In the initially described exemplary embodiment the silicon germanium layers are formed in both the n-FET region and the P-PET region. In the presently described exemplary embodiment, however, the silicon germanium buried layer 240 is formed only in the p-FET to apply stress to the channel region, to thereby improve the operating speed of the device. Although the silicon germanium lattice-mismatched region is formed in the source/drain region in the n-FET to apply any stress to the channel region, due to a different channel carrier and different stress dynamics at the n-FET, the operating speed of the device is slightly decreased, but not too much. In order to compensate for the above-described problems, in the present exemplary embodiment, the silicon germanium lattice-mismatched region may be formed only in the p-FET MOS transistor region.

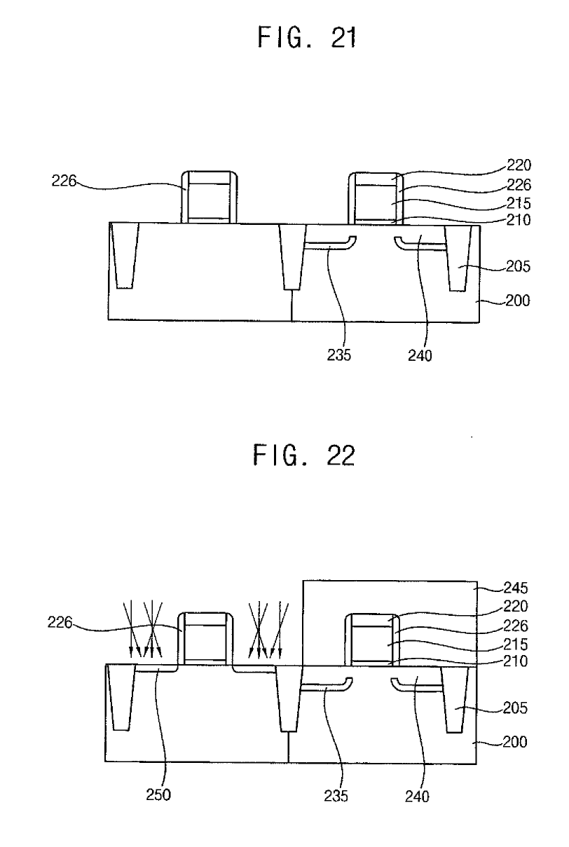

Referring to FIGS. 20 and 21, the gate sidewall sacrificial layers 223 and 225, shown in FIG. 19, remaining on the semiconductor substrate 200 and the sidewalls of the gate electrode are removed, and then a first gate sidewall layer 226 is formed on the sidewalls of the gate electrode. As mentioned above, when the gate sacrificial layer 223 is formed by a thermal oxidation process, the first gate sidewall pattern may be formed by a CVD process. Alternatively, when the gate sacrificial layer 223 is formed by a CVD process, the first gate sidewall layer 226 may be formed using a thermal oxidation layer. Thus, the same effect as performing the gate reoxidation process may be obtained.

Referring to FIG. 22, the process explained with reference to FIG. 7 is performed to form an n-type low concentration impurity region 250 in the active region of the n-FET to be subsequently formed. After a photoresist pattern 245 is formed to cover a region of the p-FET to be subsequently formed, n-type impurities may be implanted into the substrate by an ion implantation process to form the low concentration impurity region 250. Because the low concentration impurity region 250 is provided as a low concentration source/drain, and if the junction is formed deeply, the impurity region is formed laterally to consume the gate channel length, thereby to deteriorate characteristics of the device. Thus, the implantation energy should be controlled to form the impurity region to have only a small depth.

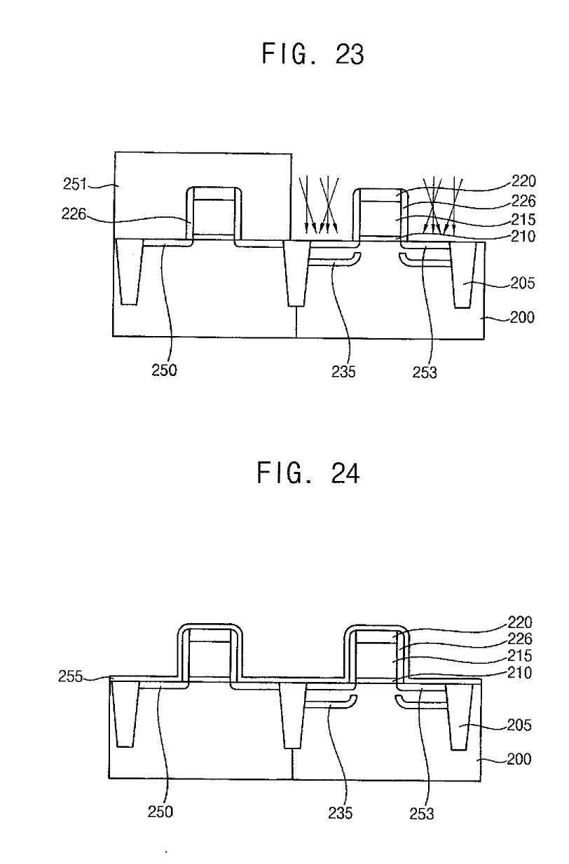

Referring to FIG. 23, the process explained with reference to FIG. 8 is performed to form a p-type low concentration impurity region 253 in an active region in which the p-FET is to be formed. After a photoresist pattern 251 is formed to cover a region where the n-FET is to be formed, p-type impurities may be implanted into the substrate by an ion implantation process represented by the arrows in FIG. 23. This process may be substantially the same as the process in FIG. 20, except for a conductive type of the ion implantation impurities. Alternatively, the process of FIG. 22 may be performed to follow the process of FIG. 23.

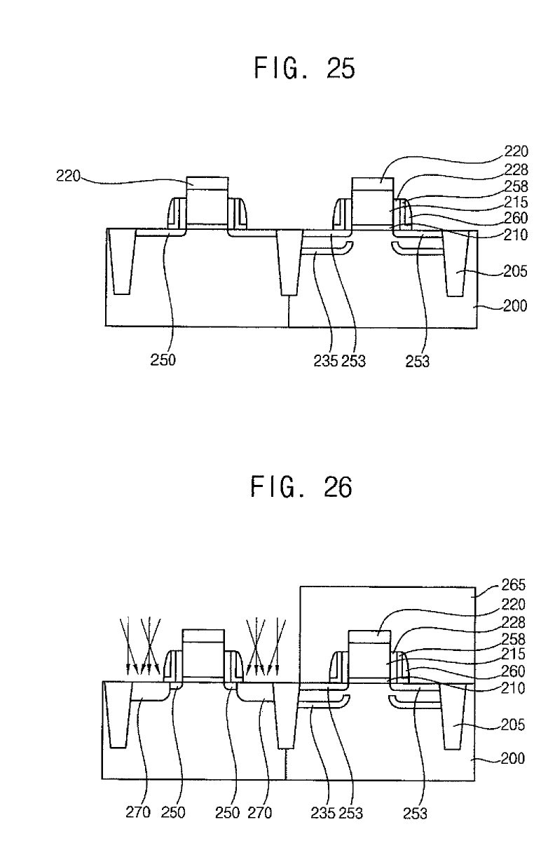

Referring to FIG. 24, the process explained with reference to FIG. 9 is performed to form a second gate sidewall layer 255 on the substrate. After forming the low concentration impurity regions 250 and 253 in the substrate for the n-FET and the p-FET to be subsequently formed, the photoresist pattern is removed and a cleaning process is performed on the semiconductor substrate. Then, the second gate sidewall layer 255 is formed on the substrate. The second gate sidewall layer 255 may be formed using a nitride layer having different properties from the first gate sidewall layer 226. The second gate sidewall layer 255 may have a thickness of about 100 Å to about 500 Å. The second gate sidewall layer 255 may be formed by a CVD process. The second gate sidewall layer 255 may include a material having an etch rate smaller than that of a third gate sidewall layer, thereby to protect the substrate from attack caused during forming a third gate sidewall pattern (see FIG. 25).

Referring to FIG. 25, after the third gate sidewall layer (not illustrated) is formed on the second gate sidewall layer 255, the first, second and third gate sidewall layers are patterned to form a first gate sidewall pattern 228, a second gate sidewall layer 258 and a third gate sidewall pattern 260. The gate sidewall patterns may be formed by an etch-back process. The second sidewall layer 255 may have a sufficient thickness and an etch rate different from the third sidewall layer, to protect the substrate from attack caused during forming of the third gate sidewall pattern 260. For example, the third gate sidewall layer may be formed using an oxide layer.

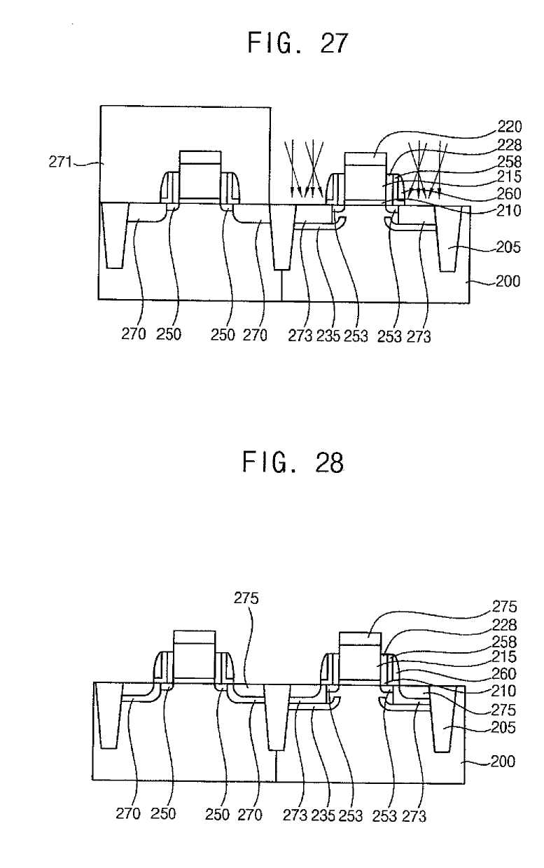

Referring to FIGS. 26 and 27, the processes explained with reference to FIGS. 11 and 12 are performed to form high concentration impurity regions 270 and 273, shown in FIG. 27. The third gate sidewall pattern 260 is used as a mask to form an n-type high concentration impurity region 270 in the region in which the n-FET MOS transistor is to be formed. Because the locally buried insulation layer is not formed in the n-FET MOS transistor region, the processes may be simplified as compared with the initially described exemplary embodiment, but diffusion of the high concentration source/drain region 270 in the n-FET MOS transistor may occur.

Referring to FIG. 27, impurities having a different conductive type are implanted to the substrate, represented by the arrows, for the p-FET MOS transistor that is to be formed, in order to form a complementary semiconductor device. In this case, a mask 271 may cover the region for the n-FET that is to be formed.

Because the high concentration impurity regions 170 and 173 are provided as a high concentration source/drain and because a metal silicide may be formed in the high concentration regions 270 and 273 by a subsequent process, the photoresist pattern and the gate hard mask 220 are removed by a wet etch process. In this exemplary embodiment, when the gate sidewall structures are formed toward a lower edge of the gate electrode, the stress concentration effect may be increased. Accordingly, after implanting the impurities, the sizes of the second and third gate sidewall patterns 258 and 260, respectively, may be further reduced to enhance the stress concentration effect.

Referring to FIG. 28, the process explained with reference to FIG. 13 is performed to form a metal silicide layer 275 on the gate electrode 215 and the high concentration impurity regions 270 and 273. The metal silicide layer 275 may be formed using a metal such as cobalt, nickel and titanium. The metal silicide layer 275 may be formed by a sputtering process. Because the thickness of the silicide layer 275 is closely related with the resistance of the source/drain region, it may be preferable for the silicide layer 275 to have a relatively large thickness. When the silicide layer 275 is formed to have a specific large thickness, however, the silicide layer 275 may be formed to be a structure by which the source/drain region is broken down by a spike effect. Accordingly, first, a low-temperature silicide layer may be formed to have a thickness of less than 200 Å by a low temperature process at a temperature of 150° C. to 450° C. For example, when cobalt is used as the silicide layer, the low-temperature silicide layer may be Co₂Si or CoSi. Accordingly, a second high-temperature process may need to be performed in order to complete the silicidation reaction. Additionally if necessary, a capping layer (not shown) such as a titanium/titanium nitride layer may be formed on the metal silicide layer 275. For example, the capping layer may be formed by a CVD process at a temperature of 300° C. to 700° C. In this case, the second high-temperature process may be omitted. The high-temperature annealing process may need to be performed to change the cobalt silicide structure, such as Co₂Si or CoSi, into a high-temperature-layered silicide structure having improved conductivity such as CoSi₂.

Because it is more advantageous that the metal suicide layer 275 formed on the high concentration impurity regions 270 and 273, respectively, has a relatively small thickness in order to prevent the spike effect that causes a break down of the structure of the source/drain region, the metal silicide layer 275 formed on the gate electrode 215 has a relatively large thickness in order to reduce the gate electrode resistance, because there is no problem about destruction of the junction. Alternatively, although illustrated as being the same in the figures, the metal silicide layers 275 formed on the impurity regions and the gate electrode may be formed to have different thicknesses.

Then, the unreacted metal layer is removed by a wet etch process. Surfaces of the remaining metal silicide layer are oxidized by a plasma oxidation process or by a thermal treatment process. The oxide layer may be used as an etch-stop layer during a following contact forming process. Furthermore, if there are any problems related to a contact resistance, after the contact forming process, the oxide layer may be removed by a wet etch process. Alternatively, instead of the oxidation process, a nitridation process may be performed to achieve for the same effect.

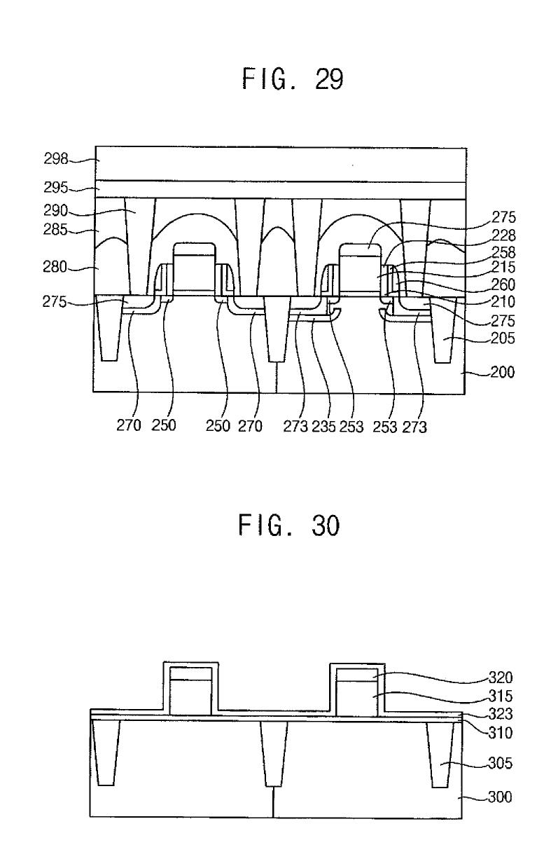

Referring to FIG. 29, the process explained with reference to FIG. 14 is performed on the substrate. After a first insulation interlayer 280 and a second insulation interlayer 285 are formed on the structure and a contact hole is formed by a photolithography process, a metal contact plug 290 is formed for subsequent connection to a metal wiring. For example, the first and second insulation interlayers 280 and 285 may include a material such as HDP, BPSG and PE-TEOS.

The metal contact plug 290 may include a material such as aluminum, tungsten and copper. The materials may be selectively used as the contact plug according to the required characteristics of the device, and thus the processes of forming the contact hole and filling the metal material may be determined according to the selected material.

Finally, a plurality of metal wirings 295, an insulation layer for protecting and insulating the wirings and a protective layer 298 for protecting the entire device are formed by subsequent processes. Then, a connection pad (not illustrated) is formed to be electrically connected to a system, to complete the semiconductor device.

FIGS. 30 to 44 are cross-sectional views illustrating a method of forming a semiconductor device in accordance with an exemplary embodiment. Most processes of the present exemplary embodiment are substantially the same as those in the two above-described exemplary embodiments. Thus, any corresponding processes will be explained compared with the two above-described exemplary embodiments, or any further repetitive explanation concerning the same process will be omitted and particular features in the present exemplary embodiment will be mainly explained. Further, additional features that are not specifically noted in the two above-described exemplary embodiments will be explained in detail.

Referring to FIG. 30, in a semiconductor device according to the present exemplary embodiment a plurality of isolation layers 305 is formed in a substrate 300. The isolation layers 305 are spaced apart from one another by a predetermined distance. The substrate 300 may comprise a semiconductor substrate, such as a silicon wafer. In the present exemplary embodiment, a gate dielectric layer 310, a gate electrode 315 and a gate hard mask 320 are substantially the same as in the initially described exemplary embodiment.

A gate sidewall layer 323 is formed on the substrate and the gate structure. The gate sidewall layer 323 may be formed by a CVD process or a thermal oxidation process. In the case of the thermal oxidation process, the gate sidewall layer may be formed by a gate reoxidation process. The gate reoxidation process can compensate for damage due to a dry etch process used in forming the gate electrode and can develop an edge portion of the gate dielectric layer into a bird's beak shape to reduce parasitic capacitance between the gate and the drain, to thereby improve characteristics of the device.

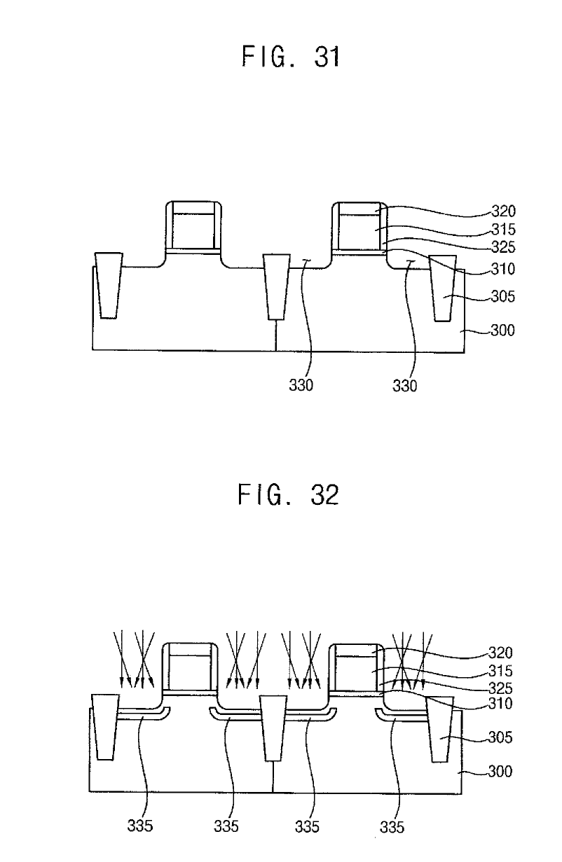

Referring to FIG. 31, the process explained with reference to FIG. 4 is performed on the substrate. The substrate is anisotropically etched using a first gate sidewall pattern 325 and the gate hard mask 320 as an etching mask to form recesses 330. For example, first a dry etch process may be performed on the substrate, and then a wet etch process may be performed to compensate for damage to the substrate caused by the dry etch process and to planarize the surfaces of the recesses. Because source/drain regions are formed in the recesses 330 by a subsequent process, the depth of the recesses 330 may be controlled according to the characteristics of the device. For example, the depth of the recesses 330 may range from about 30 nm to about 150 nm.

Referring to FIG. 32, the process explained with reference to FIG. 5 is performed on the substrate. Oxygen ions are implanted into the surface of the substrate exposed through the recesses 330, as shown by the arrows, to form locally buried insulation layers 335. The oxygen ions may be implanted under the surface of the recess 330 by an ion implantation process. Because the buried depth of the insulation layer may depend on the implantation energy, the implantation energy may be determined according to the device. According to the shape of the source/drain to be formed, the oxygen ions are implanted into the substrate at a predetermined angle and, thus, the locally buried insulation layer 335 may have a linear profile under the source/drain region and an arc profile, an end portion of which under the gate electrode is bent upwardly. Also, the oxygen ions may be symmetrically implanted into the substrate on both sides of the gate electrode such that the source/drain regions on both sides of the gate electrodes are formed to be symmetric to each other. After implanting the oxygen ions, a thermal treatment process may be performed such that the implanted oxygen ions are reacted with the substrate under an oxygen atmosphere to form the locally buried insulation layers 335. The locally buried insulation layers 335 can prevent the downward leakage in the source/drain regions and can suppress lateral depletion in the source/drain regions under the channel regions during operation of the device, to prevent the short channel effect. Accordingly, the locally buried insulation layers 335 may be bent upwardly to have an arc shape at the ends thereof. When the upper end portion of the arc shape reaches a low concentration source/drain region, the locally buried insulation layers 335 can completely prevent the short channel effect.

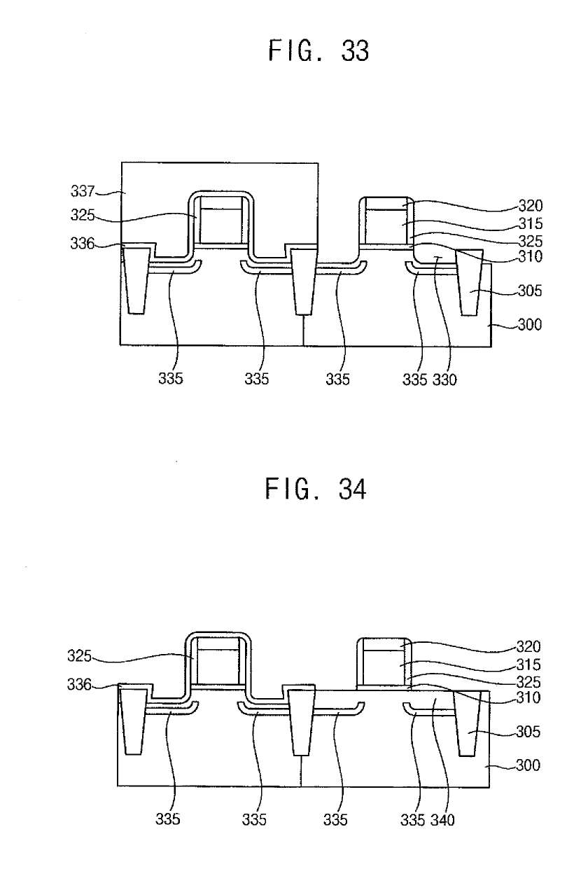

Referring to FIG. 33, a first gate sidewall sacrificial layer 336 is formed on the substrate and the gate structure. The first gate sidewall sacrificial layer 336 is used as a mask, while the recess in the p-FET MOS transistor region is buried with a silicon germanium layer, and then the first gate sidewall sacrificial layer 336 is removed. After the first gate sidewall sacrificial layer 336 is formed using an oxide layer or a nitride layer by a CVD process, a photoresist pattern 337 is formed by a photolithography process to cover the n-FET MOS transistor region and to expose the p-FET MOS transistor region.

Referring to FIG. 34, an epitaxial buried layer 340 is formed using silicon in the semiconductor substrate 300 as a seed by an epitaxial growth process to fill the recess 330 in the p-FET MOS transistor region. For example, single-crystalline silicon germanium that is different from the substrate material may be grown in the recess 330 to form the epitaxial buried layer 340. When the epitaxial buried layer 340 includes a silicon germanium layer, a lattice-mismatched region may be formed in the adjacent silicon substrate 300 by the silicon germanium layer, to apply stress to the channel region and improve the operating speed. For example, the lattice-mismatched region may be formed by an epitaxial process, such as an ultra high vacuum CVD process and a molecular beam epitaxy (MBE) process. The silicon germanium stressor may be doped in-situ with boron. For example, the silicon germanium buried layer 340 formed in the source/drain region of the p-FET may apply stress to the channel region of the p-FET, to thereby improve operating speed characteristics of the device. In the initially described exemplary embodiment, the silicon germanium layers are formed in both the n-FET region and the P-PET region. Alternatively, in the secondly described exemplary embodiment, the silicon germanium buried layer 240 is formed only in the p-FET to apply stress to the channel region, to thereby improve the operating speed of the device. Although the silicon germanium lattice-mismatched region is formed in the source/drain region in the n-FET to apply stress to the channel region, due to a different channel carrier and different stress dynamics at the n-FET, the operating speed of the device is slightly decreased but not too much. In order to compensate for such problems, in the present exemplary embodiment the silicon germanium lattice-mismatched region is formed only in the p-FET MOS transistor region, a single-crystalline silicon layer is formed in the recess 330 in the n-FET by a subsequent following process, and the lattice-mismatched region is not formed. Thus, the problem in the initially described exemplary embodiment where the silicon germanium lattice-mismatched region is formed in the source/drain region in the n-FET to deteriorate the characteristics of the device may be settled and the problem in the secondly described exemplary embodiment, where the locally buried insulation layer is not formed under the source/drain region to cause the junction leakage, may also be settled by providing a semiconductor device having a structure where the locally buried insulation layer 335 is formed under the source/drain region of the n-FET.

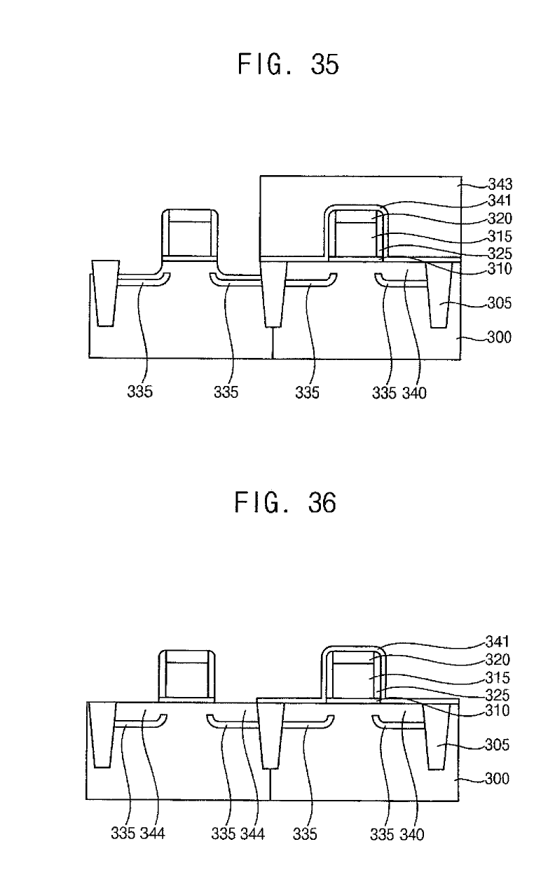

Referring to FIG. 35, a second gate sacrificial layer 341 is formed on the region where the p-FET MOS transistor is to be formed. The second gate sacrificial layer 341 is used as a mask while the recess 330 in the n-FET MOS transistor region is buried with a silicon layer 344, and then the second gate sacrificial layer 341 is removed. After the second gate sidewall sacrificial layer 341 is formed using an oxide layer or a nitride layer by a CVD process, a photoresist pattern 343 is formed by a photolithography process to cover the p-FET MOS transistor region and to expose the n-FET MOS transistor region.

Referring to FIG. 36, epitaxial buried layers 344 are formed using silicon in the semiconductor substrate 300 as a seed by an epitaxial growth process to fill the recess 330 in the n-FET MOS transistor region. For example, single-crystalline silicon, which is the same as the substrate material, may be grown in the recess 330 to form the epitaxial buried layers 344. The single-crystalline silicon layer may not cause formation of the lattice-mismatched region in the adjacent silicon substrate 300 and, thus, stress will not be applied to the channel region. In the initially described exemplary embodiment, the silicon germanium layer is formed in the n-FET region to apply stress to the channel region. Although the silicon germanium lattice-mismatched region is formed in the source/drain region in the n-FET to apply some stress to the channel region, due to a different channel carrier and different stress dynamics at the n-FET, the operating speed of the device is slightly decreased, but not by much. In order to compensate for such problems, in the presently described exemplary embodiment, the silicon germanium lattice-mismatched region is formed only in the p-FET MOS transistor region, and the single-crystalline silicon layer 344 is formed in the source/drain region in the n-FET, thereby not forming a lattice-mismatched region. Thus, the problem in the initially described exemplary embodiment, where the silicon germanium lattice-mismatched region is formed in the source/drain region in the n-FET to deteriorate the characteristics of the device, may be settled.

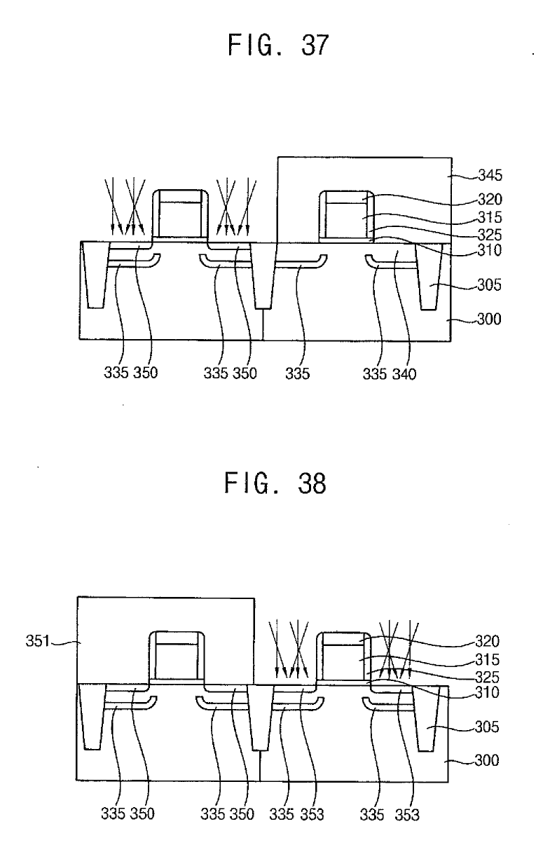

Referring to FIGS. 37 and 38, low concentration impurity regions 350 and 353 are formed respectively in the source/drain regions of the n-FET MOS transistor and the P-PET MOS transistor to be subsequently formed. The n-type low concentration impurity region 350 is formed in the active region of the n-FET. After a photoresist pattern 345 is formed to cover a region of the p-FET to be subsequently formed, n-type impurities may be implanted into the substrate by an ion implantation process to form the n-type low concentration impurity regions 350. A p-type low concentration impurity region 353 is formed in the active region of the p-FET. After a photoresist pattern 351 is formed to cover a region of the n-FET to be subsequently formed, p-type impurities may be implanted into the substrate by an ion implantation process, shown by the arrows, to form the p-type low concentration impurity region 353.

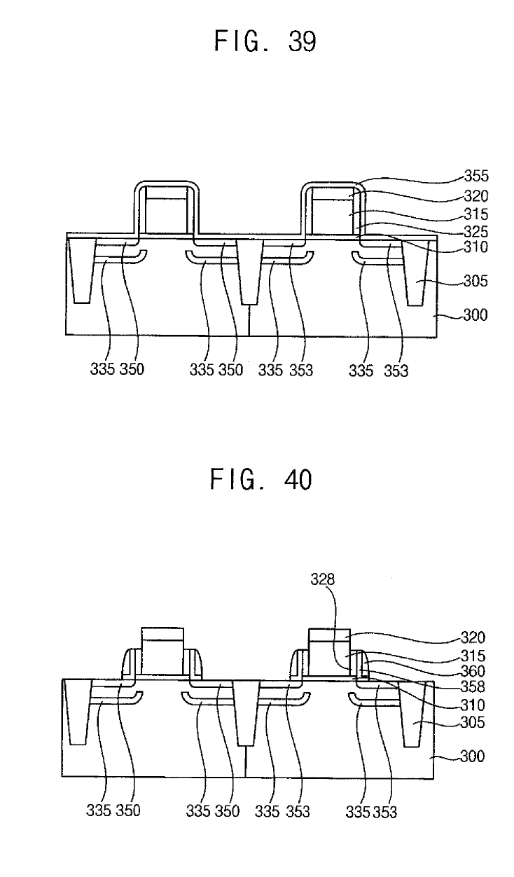

Referring to FIG. 39, after forming the low concentration impurity regions 350 and 353 in the substrate where the n-FET and the p-FET are to be formed in, the photoresist pattern is removed and a cleaning process is performed on the semiconductor substrate, then, a second gate sidewall layer 355 is formed on the substrate. The second gate sidewall layer 355 may be formed using a nitride layer having different properties from the first gate sidewall layer 225. The second gate sidewall layer 355 may have a thickness of about 100 Å to about 500 Å, and the second gate sidewall layer 355 may be formed by a CVD process. The second gate sidewall layer 355 may include a material having an etch rate smaller than that of a third gate sidewall layer, to protect the substrate from attack that might be caused during the forming of a third gate sidewall pattern (see FIG. 40).

Referring to FIG. 40, after the third gate sidewall layer (not illustrated) is formed on the second gate sidewall layer 355, the first, second and third gate sidewall layers are patterned to form a first gate sidewall pattern 328, a second gate sidewall layer 358 and a third gate sidewall pattern 360. The gate sidewall patterns may be formed by an etch-back process. The second sidewall layer 355 may have a sufficient thickness and an etch rate different from the third sidewall layer, to protect the substrate from attack that might be caused during forming of the third gate sidewall pattern 360. For example, the third gate sidewall layer may be formed using an oxide layer.

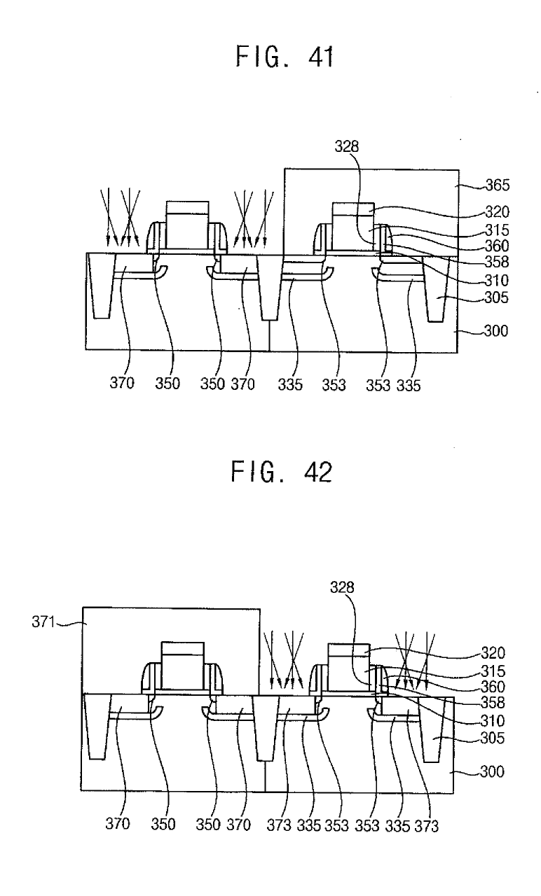

Referring to FIG. 41, the third gate sidewall pattern 360 is used as a mask to form an n-type high concentration impurity region 370 in the region where the n-FET MOS transistor is to be formed. In the secondly described exemplary embodiment, the locally buried insulation layer is not formed under the source/drain region to cause the junction leakage, whereas in the presently described exemplary embodiment, the problem in the secondly described exemplary embodiment may be settled by the locally buried insulation layer formed under the source/drain region of the n-FET.

Referring to FIG. 42, impurities having a different conductive type are implanted to the substrate, shown by the arrows, for the p-FET MOS transistor to be subsequently formed, in order to form a complementary semiconductor device. In this case, a mask 371 may be formed to cover the region where the n-FET is to be formed.

Because the high concentration impurity regions 370 and 373 are provided as a high concentration source/drain and a metal silicide may be formed in the high concentration regions 370 and 373 by a subsequent process, the photoresist pattern and the gate hard mask 320 are removed by a wet etch process. In this exemplary embodiment, when the gate sidewall structures are formed toward a lower edge of the gate electrode, the stress concentration effect may be increased. Accordingly, after implanting the impurities, the sizes of the second and third gate sidewall patterns 358 and 360 may be further reduced to enhance the stress concentration effect and improve the operating speed.

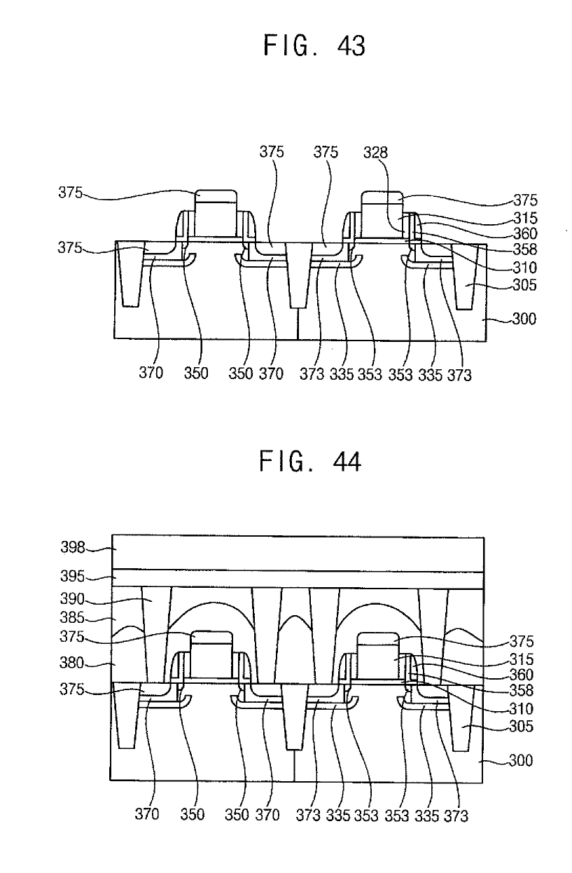

Referring to FIG. 43, a metal silicide layer 375 is formed on the gate electrode 315 and the high concentration impurity regions 370 and 373. The metal silicide layer 375 may be formed using a metal, such as cobalt, nickel and titanium. The metal silicide layer 375 may be formed by a sputtering process. Because the thickness of the silicide layer 375 is closely related with the resistance of the source/drain region, it may be preferable for the silicide layer 375 to have a relatively large thickness. When the silicide layer 375 is formed to have a specific large thickness, however, the silicide layer 375 may be formed as a structure by which the source/drain region is broken down by a spike effect. Accordingly, a low-temperature suicide layer may be formed first to have a thickness of less than 200 Å by a low temperature process at a temperature of 150° C. to 450° C. For example, when cobalt is used as the silicide layer, the low-temperature silicide layer may be Co₂Si or CoSi. Accordingly, a second high-temperature process may need to be performed in order to complete the silicidation reaction. Additionally if necessary, a capping layer (not shown) such as a titanium/titanium nitride layer may be formed on the metal silicide layer 375. For example, the capping layer may be formed by a CVD process at a temperature of 300° C. to 700° C. In this case, the second high-temperature process may be omitted. The high-temperature annealing process may need to be performed to change the cobalt silicide structure, such as Co₂Si or CoSi, into a high-temperature-layered silicide structure having improved conductivity, such as CoSi₂.

Because it is more advantageous that the metal silicide layer 375 formed on the high concentration impurity regions 370 and 373 has a relatively small thickness in order to prevent the spike effect that causes break down of the structure of the source/drain region, and that the metal silicide layer 375 formed on the gate electrode 315 has a relatively large thickness in order to reduce the gate electrode resistance, there is no problem involving destruction of the junction. Alternatively, although not illustrated in the figures, the metal silicide layers 375 formed on the impurity regions and the gate electrode may be formed to have different thicknesses.

Then, the unreacted metal layer is removed by a wet etch process, and surfaces of the remaining metal silicide layer are oxidized by a plasma oxidation process or a thermal treatment process. The oxide layer may be used as an etch-stop layer during a subsequent contact forming process. Further, if there are any problems related to a contact resistance, after the contact forming process, the oxide layer may be removed by a wet etch process. Alternatively, instead of the oxidation process, a nitridation process may be performed to achieve the same effect.

Referring to FIG. 44, after a first insulation interlayer 380 and a second insulation interlayer 385 are formed on the structure and a contact bole is formed by a photolithography process, a metal contact plug 390 is formed to be connected to a metal wiring (not shown). For example, the first and second insulation interlayers 380 and 385 may include a material, such as HDP, BPSG and PE-TEOS.

The metal contact plug 390 may include a material such as aluminum, tungsten and copper. The materials may be selectively used as the contact plug according to the required characteristics of the device and, thus, the processes of forming the contact hole and filling the metal material may be determined according to the selected material.

Finally, a plurality of metal wirings 395, an insulation layer (not shown) for protecting and insulating the wirings, and a protective layer 398 for protecting the entire device are formed by subsequent processes. Then, a connection pad (not illustrated) is formed to be electrically connected to a system, to complete the semiconductor device.

As described above, in a semiconductor device in accordance with exemplary embodiments of the present invention, stress may be applied so as to be concentrated on a channel to provide high operating speed. Furthermore, a locally buried insulation layer may be formed under a source/drain region to prevent junction leakage. Furthermore, a triple-layer gate sidewall structure may be provided on a gate electrode to protect an active region from attack that might be caused during removing of a gate sidewall layer.

The foregoing is illustrative of exemplary embodiments of the present invention and is not to be construed as limiting thereof. Although a few exemplary embodiments have been described, those of ordinary skill in the art will readily appreciate that many modifications are possible in the exemplary embodiments without materially departing from the novel teachings and advantages of the present invention. Accordingly, all such modifications are intended to be included within the scope of the present invention as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

1. A semiconductor device, comprising:
a substrate having an n-type field effect transistor (n-FET) region and a p-type field effect transistor (p-FET) region;
an isolation layer formed in the substrate to define an active region;
a gate structure formed on the substrate, the gate structure including a plurality of sidewall layers and a gate electrode;
a source/drain impurity layer formed in the substrate adjacent the gate structure;
a metal silicide layer formed on the source/drain impurity layer and on the gate structure;
a locally buried insulation layer formed in a side of a channel extending along under the source/drain impurity layer; and
a heterojunction structure layer formed in the source/drain region in the p-FET region to induce stress therein.

2. The semiconductor device of claim 1, wherein the heterojunction structure layer comprises a material different from a material of the substrate.

3. The semiconductor device of claim 2, wherein the heterojunction structure layer comprises silicon germanium.

4. The semiconductor device of claim 1, wherein the sidewall layers are formed on a middle portion to a lower portion of the gate electrode.

5. The semiconductor device of claim 1, wherein the locally buried insulation layer extends along under the source/drain impurity layer, having an arc profile in the channel.

6. A semiconductor device comprising:
a substrate having an n-FET region and a p-FET region;
an isolation layer formed in the substrate to define an active region;
a gate structure formed on the substrate, the gate structure including a plurality of sidewall layers and a gate electrode;
a source/drain impurity layer formed in the substrate adjacent the gate structure;
a metal silicide layer formed on the source/drain impurity layer and on the gate structure;
a locally buried insulation layer formed in a side of a channel extending along under the source/drain impurity layer of the p-FET region; and
a heterojunction structure layer formed in the source/drain region in the p-FET region to induce stress therein,
wherein the heterojunction structure layer comprises silicon germanium.

7. The semiconductor device of claim 6, wherein the sidewall layers have a triple-layer structure.

8. The semiconductor device of claim 6, wherein the metal silicide layer comprises cobalt silicide.

9-18. (canceled)
